(19) United States
(12) Patent Application Publication
(10) Pub. No.: US 2026/0110593 A1
(43) Pub. Date: Apr. 23, 2026

(54) METHOD FOR PREDICTING THE LIFETIME OF EUV PELLICLES

(71) Applicant: FINE SEMITECH CORP., Hwaseong-si (KR)

(72) Inventors: Eil Ho JUNG, Hwaseong-si (KR); Sang Jin CHO, Hwaseong-si (KR); So Yoon LEE, Hwaseong-si (KR); Lan YU, Hwaseong-si (KR); Jae Hyuck CHOI, Hwaseong-si (KR)

(21) Appl. No.: 19/359,711

(22) Filed: Oct. 16, 2025

(30) Foreign Application Priority Data
Oct. 17, 2024 (KR) 10-2024-0142211

(51) Int. Cl. G01M 11/02

(52) U.S. Cl. CPC G01M 11/0285; G01M 11/0228

(57) ABSTRACT

A method for predicting the lifetime of an EUV pellicle includes a) acquiring transmittance data of an EUV pellicle over a wavelength band ranging from an infrared region to an ultraviolet region, b) acquiring complex refractive index data of the EUV pellicle over the wavelength band ranging from the infrared region to the ultraviolet region, c) acquiring information on the relationship between density and transmittance of the EUV pellicle as a function of wavelength, and d) measuring the transmittance of the EUV pellicle for at least one measurement beam having a wavelength within the wavelength band, extracting an estimated density of the EUV pellicle on the basis of the measured transmittance and the information on the relationship between density and transmittance acquired in the step c), and predicting a remaining lifetime of the EUV pellicle on the basis of the estimated density.

### CROSS REFERENCE TO RELATED APPLICATION

The present application claims priority to Korean Patent Applications No. 10-2024-0142211, filed on Oct. 17, 2024, the entire contents of which are incorporated herein for all purposes by this reference.

### BACKGROUND

### Technical Field

The present disclosure relates to a method for predicting the lifetime of an EUV pellicle and, more particularly, to a method for predicting the lifetime of an EUV pellicle using transmittance of the EUV pellicle.

### Description of the Related Art

In EUV lithography, EUV light is used to transfer the pattern of a photomask onto a substrate (wafer). An EUV pellicle serves to protect a photomask from particle contamination and damage. In semiconductor manufacturing processes, it is very important to maintain the integrity of a photomask and ensure optimal performance.

One of the main issues in the EUV lithography environment is hydrogen within the EUV chamber. Hydrogen can move freely within the chamber. EUV light can generate hydrogen radicals from hydrogen. Hydrogen radicals are highly chemically reactive. Materials constituting a pellicle membrane of an EUV pellicle, such as silicon and carbon nanotubes (CNTs), are vulnerable to etching by hydrogen radicals.

Etching by hydrogen radicals poses a serious threat to the performance of a pellicle. The lifetime of a pellicle is directly affected by the duration of exposure to hydrogen radicals.

At present, the lifetime of an EUV pellicle is mainly predicted by measuring changes in the transmittance of EUV light. However, this approach has limitations. EUV light is absorbed by various materials within a scanner environment. The transmittance of EUV light can be affected by the conditions of the chamber and the characteristics of the pellicle membrane materials. Further, since the transmittance of EUV light does not respond sensitively to the degree of etching of the pellicle membrane, it is difficult to predict the accurate lifetime.

In general, the thickness of a thin film can be determined through optical spectroscopic modeling using spectroscopic ellipsometry (SE). However, for thin films like pellicle membranes, which are transparent and have very low reflectivity, it is very difficult to obtain a valid signal using SE. In particular, the thickness of a free-standing (FS) membrane, which is not supported by a substrate, cannot be determined through optical spectroscopic modeling based on measurements using SE. Therefore, lifetime prediction based on thickness and density measurements using spectroscopic ellipsometry is also difficult to apply.

### PRIOR ART DOCUMENTS

### Patent Documents

Korean Patent No. 10-1948416

Korean Patent No. 10-0252937

### SUMMARY

An objective of the present disclosure is to provide a novel method capable of more accurately predicting the lifetime of an EUV pellicle.

In order to achieve the objectives, the present disclosure provides a method for predicting the lifetime of an EUV pellicle, the method including: a) acquiring transmittance data of an EUV pellicle over a wavelength band ranging from an infrared region to an ultraviolet region; b) acquiring complex refractive index data of the EUV pellicle over the wavelength band ranging from the infrared region to the ultraviolet region; c) acquiring information on a relationship between density and transmittance of the EUV pellicle as a function of wavelength by performing optical modeling using the transmittance data and the complex refractive index data; and d) measuring the transmittance of the EUV pellicle for at least one measurement beam having a wavelength within the wavelength band ranging from the infrared region to the ultraviolet region, extracting an estimated density of the EUV pellicle on the basis of the measured transmittance and the information on the relationship between density and transmittance acquired in the step c), and predicting a remaining lifetime of the EUV pellicle on the basis of the estimated density.

Further, the wavelength band in the step a) may include a wavelength band from 190 nm to 200 μm.

Further, the wavelength band in the step a) may include a wavelength band from 190 nm to 1000 nm.

Further, the step a) may include: a-1) acquiring transmittance data in the wavelength band from 770 nm to 200 μm using an FT-IR type spectrometer; and a-2) acquiring transmittance data in the wavelength band from 190 nm to 1000 nm using a UV-Vis type spectrophotometer. Further, the step b) may include: b-1) attaching a pellicle membrane of the EUV pellicle to a substrate; and b-2) acquiring complex refractive index data of the EUV pellicle using a spectroscopic ellipsometer.

Further, the step c) may be a step that uses Intensity Transfer Matrix Method.

Further, the step d) may include: d-1) selecting at least one measurement beam; d-2) measuring transmittance of the EUV pellicle for the selected measurement beam; d-3) extracting an estimated density of the EUV pellicle on the basis of the transmittance measured in the step d-2) and information on the relationship between density and transmittance of the EUV pellicle acquired in the step c); and d-4) predicting a remaining lifetime of the EUV pellicle on the basis of the estimated density extracted in the step d-3).

Further, the step d-1) may include: identifying an absorption mode that most significantly contributes to the amount of absorption of a pellicle membrane; determining g a full width at half maximum (FWHM) of the absorption mode; an FWHM outer wavelength range selection step of selecting a region outside the FWHM on the basis of the FWHM of the absorption mode; and selecting a wavelength of the measurement beam in the selected wavelength range outside the FWHM.

Further, the selecting a wavelength of the measurement beam may include: a linear characteristic evaluation step of identifying a wavelength at which transmittance varies linearly with changes in density in the selected wavelength range outside the FWHM; and a wavelength selection step of selecting a wavelength at which the linear relationship is most pronounced as the wavelength of the measurement beam.

According to the present disclosure, the lifetime of an EUV pellicle can be predicted more accurately. This can contribute to preventing contamination of a photomask and maintaining the yield of a lithography process.

### BRIEF DESCRIPTION OF THE DRAWINGS

FIG. 1 is a flowchart of a method for predicting the lifetime of an EUV pellicle according to an embodiment of the present disclosure;

FIG. 2 is a view showing an example of an EUV pellicle;

FIG. 3 shows the transmittance of a carbon nanotube pellicle membrane measured using an FT-IR spectrometer and a UV-Vis spectrometer;

FIG. 4 shows the result of optical modeling of the transmittance data of FIG. 3 by applying density and thickness information derived from the complex refractive index;

FIG. 5 is a graph showing the relationship between transmittance and relative density as a function of wavelength;

FIG. 6 is a transmittance distribution diagram according to relative density and wavelength;

FIG. 7 is a flowchart of steps for predicting the remaining lifetime of an EUV pellicle; and

FIG. 8 is a flowchart of steps of selecting a measurement beam.

### DETAILED DESCRIPTION

Hereinafter, embodiments of the present disclosure are described in detail with reference to the accompanying drawings. However, the present disclosure is not limited to the following embodiments and can be implemented in various ways different from one another, and the embodiments are provided to complete the present disclosure and to completely inform those skilled in art of the scope of the present disclosure. The same components are given the same reference number in the drawings.

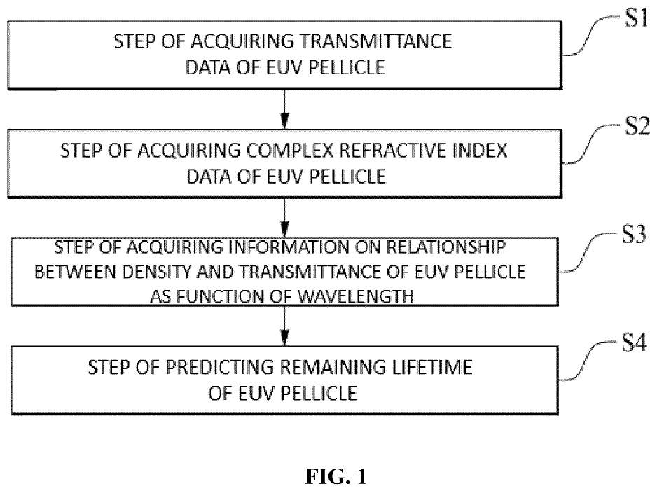

FIG. 1 is a flowchart of a method for predicting the lifetime of an EUV pellicle according to an embodiment of the present disclosure.

As shown in FIG. 1, a method for predicting the lifetime of an EUV pellicle according to an embodiment of the present disclosure includes step S1 of acquiring transmittance data of an EUV pellicle, step S2 of acquiring complex refractive index data of the EUV pellicle, step S3 of acquiring information on the relationship between density and transmittance of the EUV pellicle as a function of wavelength, and step S4 of predicting the remaining lifetime of the EUV pellicle.

First, step S1 of acquiring transmittance data of an EUV pellicle in a wavelength band from an infrared region to an ultraviolet region is described.

In step S1, a wavelength band including at least a visible light region and an ultraviolet region is set as a wavelength band to be measured.

For example, a wavelength band including 190 nm to 200 μm may be selected as a wavelength band for acquiring transmittance data. For example, a wavelength band including 190 nm to 1000 nm may be selected as a wavelength band for acquiring transmittance data.

This range allows the transmittance of pellicles to be sufficiently evaluated and enables the performance of EUV pellicles to be analyzed under other wavelength conditions, which allow accurate and easy evaluation, rather than in the EUV.

As equipment for measuring transmittance data, an FT-IR spectrometer (Fourier Transform Infrared Spectrometer) and a UV-Vis spectrometer (Ultraviolet-Visible Spectrophotometer) may be used.

The FT-IR spectrometer is mainly used to measure transmittance data in the wavelength band from 770 nm to 200 μm, and the UV-Vis spectrometer is mainly used to measure transmittance data in the range from 190 nm to 1000 nm. In this way, the transmittance characteristics of EUV pellicles can be acquired over a wide wavelength range using multiple pieces of equipment.

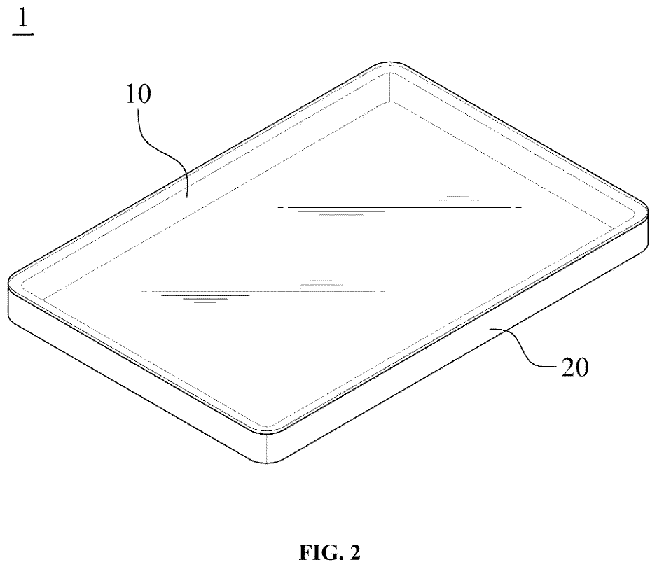

FIG. 2 is a view showing an example of an EUV pellicle. As shown in FIG. 2, an EUV pellicle 1 includes a pellicle frame 20 and a pellicle membrane 10.

In the present disclosure, the transmittance of an EUV pellicle refers to the transmittance of the pellicle membrane 10.

The pellicle membrane 10 may have a multilayer structure including a core layer and a capping layer (or coating layer). The core layer may be made of various materials having high transmittance to EUV, such as carbon nanotubes, silicon, metal silicide, or graphene, and the capping layer may be made of materials capable of protecting the core layer from hydrogen radicals, such as a silicon compound or metal silicide. The pellicle membrane may also have a single-layer structure.

In the case of a multilayer structure, transmittance can be measured for each lamination step. That is, the transmittance of the core layer can be measured, and the transmittance of a multilayer pellicle thin film composed of “core layer +capping layer” can be measured. By analyzing this using the transfer matrix method, the transmittance of each of the core layer and the capping layer can be acquired. By acquiring the transmittance of individual layers from the transmittance of the multilayer thin film, the density and thickness of the core layer and the capping layer can also be modeled.

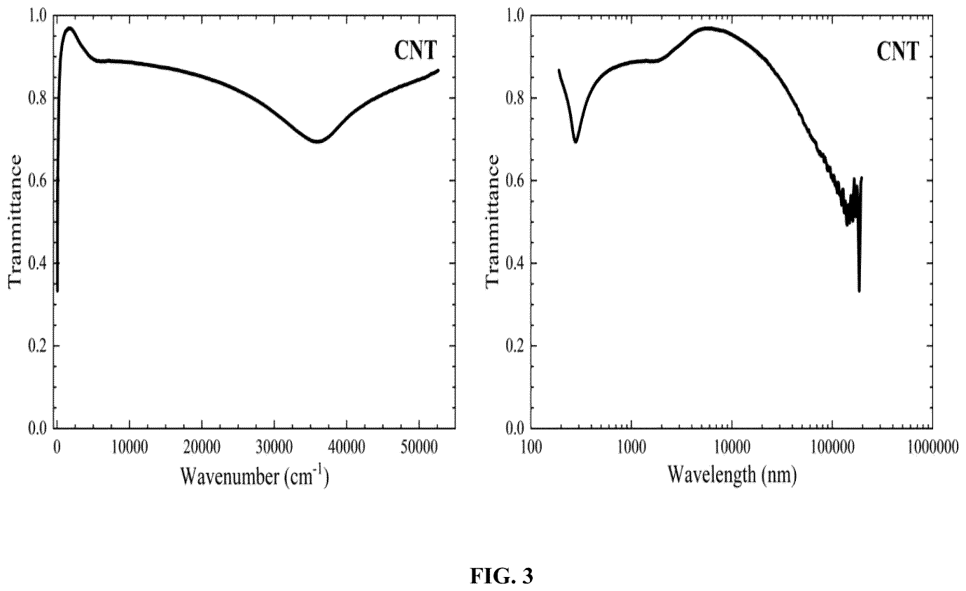

FIG. 3 shows the transmittance of a carbon nanotube pellicle membrane measured using an FT-IR spectrometer and a UV-Vis spectrometer.

Next, step S2 of acquiring complex refractive index data of an EUV pellicle in a wavelength range from an infrared region to an ultraviolet region is described.

Complex refractive index data can be acquired through an optical analysis process of data measured using spectroscopic ellipsometry, a Fourier transform infrared spectrometer, and a UV-Vis spectrophotometer. Complex refractive index data is represented as a spectrum according to the wavelength of light. Complex refractive index data is intrinsic material property information.

Spectroscopic ellipsometry is an analytical method that investigates the optical and structural properties of a material using information on the change in polarization ratio after light incident on the material is reflected from or transmitted through the surface, depending on the complex refractive index and thickness (optical path) of the medium.

This step includes step S21 of attaching the pellicle membrane of an EUV pellicle to a substrate and step S22 of acquiring complex refractive index data of the EUV pellicle using a spectroscopic ellipsometer.

A substrate is necessarily required to acquire complex refractive index data of a transparent thin film with an absorption coefficient (k) close to 0 using a spectroscopic ellipsometer. Therefore, it is necessary to separate a freestanding pellicle membrane from a pellicle frame and attach it to a substrate. Smooth and transparent substrates such as silicon, sapphire, and glass are mainly used as the substrate. The substrate must have a flat surface and be free of defects. A pellicle membrane can be attached to a substrate by methods such as wet transfer, dry transfer, and deposition.

Since a spectroscopic ellipsometer provides only indirect information through the polarization ratio (amplitude ratio Ψ, phase difference Δ) between the incident circularly polarized beam on the surface of a material and the reflected elliptically polarized beam, ellipsometric modeling is required to acquire information on the properties or thickness of a pellicle membrane from the measured spectrum. Through this process, complex refractive index data of EUV pellicles can be acquired.

For example, using a spectroscopic ellipsometer, a circularly polarized beam is incident at angles ranging from 61° to 70° in 1° increments, and the reflected beam is analyzed to acquire the polarization ratio such as the phase difference and amplitude ratio of the P and S waves. Then, through an optical modeling process in which the thickness, refractive index (n), and absorption coefficient (k) of the pellicle membrane are set as variables, complex refractive index data satisfying the measured polarization ratio can be acquired.

Further, complex refractive index data can also be acquired by measuring transmittance and reflectance using other equipment besides a spectroscopic ellipsometer, such as a FT-IR spectrometer (Fourier transform infrared spectrometer) and a UV-Vis spectrophotometer.

As a method for acquiring precise and highly reliable complex refractive index data, data is acquired, and both the method using a polarization ratio described above and the method using transmittance and reflectance are employed, whereby precision and reliability are ensured through cross-validation.

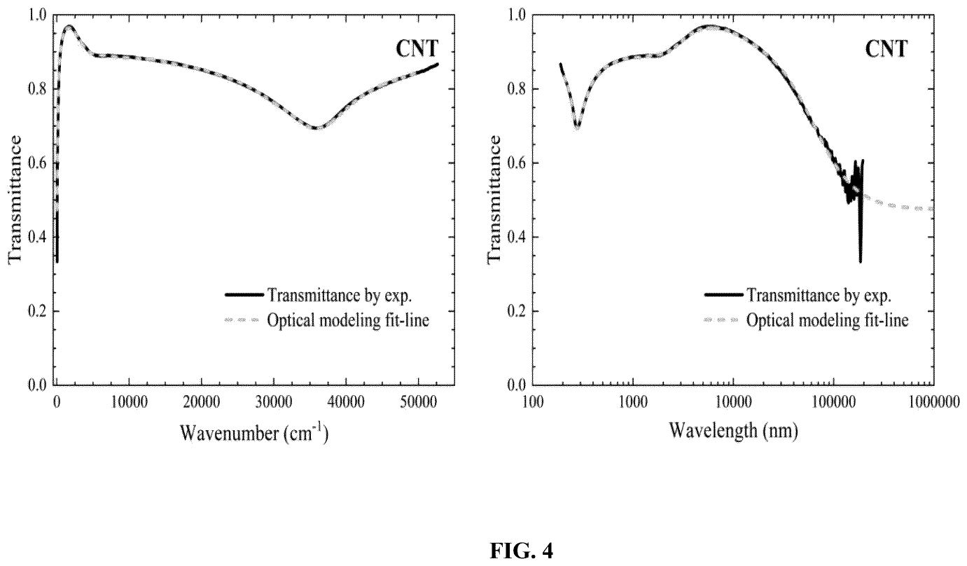

FIG. 4 shows the result of optical modeling of the transmittance data of FIG. 3 by applying density and thickness information derived from a complex refractive index. The result of optical modeling and the result of measuring transmittance are in close agreement.

Next, step S3 of acquiring information on the relationship between density and transmittance of the EUV pellicle as a function of wavelength by performing optical modeling using transmittance data and complex refractive index data is described.

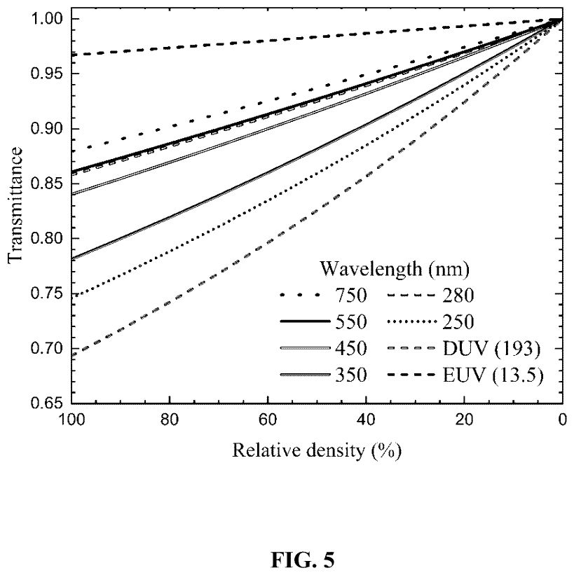

In this step, for example, as shown in FIG. 5, a graph representing the relationship between transmittance and relative density at various wavelengths can be acquired. In FIG. 5, the X-axis represents relative density and the Y-axis represents transmittance. A value of 0.65 corresponds to 65% transmittance. EUV refers to extreme ultraviolet and DUV refers to deep ultraviolet. As can be seen in FIG. 5, at shorter wavelengths (e.g., 280 nm), transmittance decreases more sharply as relative density decreases. Conversely, at longer wavelengths (e.g., 750 nm), transmittance is less sensitive to changes in relative density. However, it can be seen that EUV transmittance is hardly affected by changes in relative density. Therefore, EUV is unsuitable for measuring relative density.

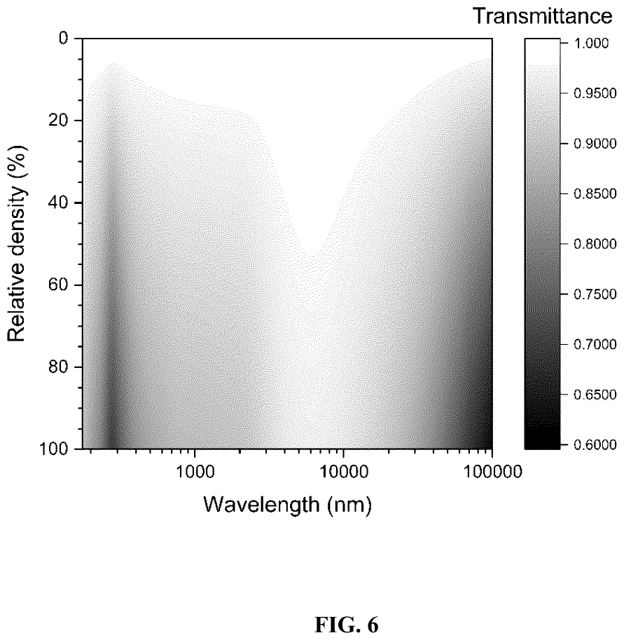

Further, as shown in FIG. 6, a transmittance distribution map as a function of relative density and wavelength can also be acquired. The X-axis represents wavelength, which increases from left to right. The Y-axis represents relative density. Transmittance is represented by color. White indicates high transmittance and black indicates low transmittance. This graph shows the variation of transmittance as a function of relative density and wavelength in a two-dimensional map format.

Transmittance is defined as a function of complex refractive index, density, and thickness. Therefore, when the transmittance of an EUV pellicle is measured with a complex refractive index known, density and thickness information of the pellicle film can be extracted. Conversely, transmittance data can also be derived using thickness and density as variables. That is, with complex refractive index data ensured, density and thickness information can be acquired on the basis of transmittance data.

In this step, an optical model is established, and the parameters of the optical model are adjusted so that the difference between the simulation results using the optical model and the actually measured transmittance data is minimized. The parameters of the optical model may include transmittance, complex refractive index, density, and thickness.

Once the optical model is optimized through the optimization process, the relationship between the density and transmittance of the pellicle membrane is analyzed. Then, a mathematical model representing the relationship between the density and transmittance of the pellicle is developed.

Intensity Transfer Matrix Method (ITMM) may be used for such optical modeling. The ITMM is a method of mathematically modeling the propagation of light in an optical system. Each layer is represented by a transfer matrix, and the transfer matrices of all layers are multiplied to calculate the overall system transfer matrix. Then, transmittance is calculated from the overall system transfer matrix. The measured transmittance is compared with the prediction results of the model, and the predicted density and thickness are adjusted.

Next, step S4 of predicting the remaining lifetime of the EUV pellicle is described.

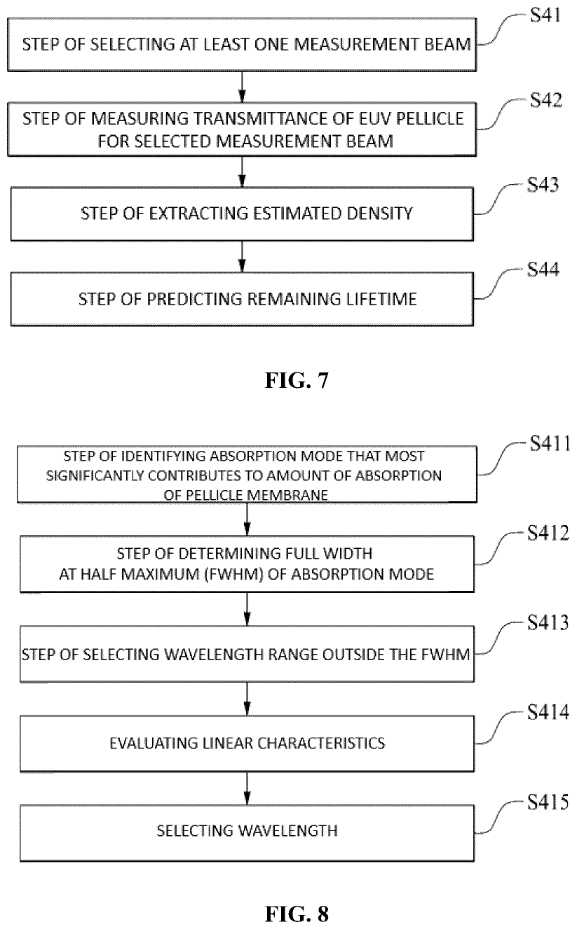

As shown in FIG. 7, step S4 includes step S41 of selecting at least one measurement beam, step S42 of measuring the transmittance of the EUV pellicle for the selected measurement beam, step S43 of extracting estimated density, and step S44 of predicting a remaining lifetime.

As shown in FIG. 8, step S41 of selecting at least one measurement beam includes step S411 of identifying the absorption mode that most significantly contributes to the amount of absorption of the pellicle membrane, step S412 of determining the full width at half maximum (FWHM) of the absorption mode, step S413 of selecting a wavelength range outside the FWHM, step S414 of evaluating linear characteristics, and step S415 of selecting a wavelength.

Step S411 of identifying the absorption mode that most significantly contributes to the amount of absorption of the pellicle membrane is a process of analyzing the extent to which a material absorbs light at specific wavelengths. In this step, the absorption spectrum of the material is first measured through spectroscopic analysis. Then, the most prominent absorption peak (wavelength band with a high amount of absorption) in the absorption spectrum is identified. This peak reflects an absorption mode associated with electronic transition, a vibrational mode, or a rotational mode within the material.

Absorption modes include an electronic absorption mode, a vibrational absorption mode, a rotational absorption mode, a Raman absorption mode, a plasmonic absorption mode, a resonance absorption mode, a phonon absorption mode, and a magnetic absorption mode. For example, when a carbon nanotube (CNT) is used as the material of a pellicle membrane, the absorption mode may be the plasmonic absorption mode.

Step S412 of determining the full width at half maximum (FWHM) of the corresponding absorption mode is a process of measuring the width of the absorption peak in an absorption spectrum. In this step, the maximum value of the absorption peak is first determined. Then, the absorption ratio (or absorbance) corresponding to half of the maximum value is calculated. Two wavelengths corresponding to this half-absorption ratio value are then identified, and the difference between them is calculated. This difference corresponds to the full width at half maximum (FWHM) and represents the width of the corresponding absorption mode. Step S413 of selecting a wavelength range outside the full width at half maximum (FWHM) is a step of selecting a region outside the FWHM where the influence of the absorption mode is reduced, on the basis of the FWHM calculated in the previous step S412. The selection of this region aims to choose a wavelength at which the density information of the core layer can be expressed as a linear function rather than an exponential function, that is, to select a wavelength at which the absorption by the coating layer is very small.

In the absorption wavelength band, the transmittance increases exponentially as the density value decreases, so it is difficult to intuitively determine the density from the transmittance data. For example, when a carbon nanotube is used as a pellicle membrane, the central value of the absorption wavelength band is approximately 280 nm. As shown in FIG. 7, the transmittance of light having a wavelength of 280 nm varies exponentially.

Step S414 of evaluating linear characteristics is a step of analyzing the relationship between transmittance and relative density in the wavelength range outside the full width at half maximum. In this step, a wavelength at which the transmittance and density exhibit a linear relationship is identified. The linear relationship means that changes in transmittance as a function of changes in density increase or decrease at a constant rate. This is advantageous for simplifying the prediction model and improving accuracy.

Step S415 of selecting a wavelength is a step of selecting a wavelength at which the linear relationship is most pronounced. This wavelength serves as a reference for effectively monitoring changes in the density of the pellicle membrane. For example, as shown in FIG. 7, a wavelength of 550 nm, which is outside the absorption wavelength band and exhibits a linear relationship with transmittance and density, can be selected as the wavelength of the measurement beam.

Step S42 of measuring the transmittance of the EUV pellicle membrane for the selected measurement beam is a step of passing a measurement beam of the selected wavelength through the pellicle membrane, measuring the intensity of light after passing through the pellicle membrane, and calculating transmittance by calculating the ratio between the intensity of the transmitted beam and the intensity of the original beam.

Step S43 of extracting estimated density is a step of extracting estimated density using the relationship between the transmittance calculated in the previous step S42 and the transmittance and pellicle membrane density acquired in step S3.

In step S44 of predicting the remaining lifetime, the estimated density extracted in the previous step S43 is used to determine how much the pellicle has been damaged in its current state. This step is also a step of calculating the time until the pellicle reaches a critical density at which it loses its functionality. This time is the remaining lifetime of the pellicle. A remaining lifetime can be calculated considering environmental conditions such as the intensity of EUV and the concentration of hydrogen radicals, the degradation rate of a pellicle membrane, etc.

When a pellicle membrane consists of multiple layers made of different materials, the density change of each layer can be acquired using transmittance data acquired using measurement beams of different wavelengths. In this case, using at least as many measurement beams as the number of layers in the pellicle membrane is advantageous for accurate measurement. For example, if a pellicle membrane consists of two layers, two or more measurement beams of different wavelengths can be used. If possible, using more transmittance data than the number of layers is even more advantageous in that it can improve reliability.

However, layers that do not affect transmittance may be excluded from the number of layers. For example, if a pellicle membrane includes a coating layer and a core layer, and the coating layer does not affect the transmittance of the measurement beam while only the core layer does, only a single measurement beam may be used.

Even when a pellicle membrane is composed of multiple materials, it is advantageous to use at least as many transmittance data as the number of materials. If a membrane includes multiple layers and each layer is made of multiple materials, transmittance data should be acquired in a number that accounts for both the number of layers and the number of materials. Although the present disclosure was described above with reference to drawings and embodiments, it should be understood that the present disclosure may be changed and modified in various ways by those skilled in the art, without departing from the spirit of the present disclosure described in claims.

1. A method for predicting the lifetime of an EUV pellicle, the method comprising:
a) acquiring transmittance data of an EUV pellicle over a wavelength band ranging from an infrared region to an ultraviolet region;
b) acquiring complex refractive index data of the EUV pellicle over the wavelength band ranging from the infrared region to the ultraviolet region;
c) acquiring information on a relationship between density and transmittance of the EUV pellicle as a function of wavelength by performing optical modeling using the transmittance data and the complex refractive index data; and
d) measuring the transmittance of the EUV pellicle for at least one measurement beam having a wavelength within the wavelength band ranging from the infrared region to the ultraviolet region, extracting an estimated density of the EUV pellicle on the basis of the measured transmittance and the information on the relationship between density and transmittance acquired in the step c), and predicting a remaining lifetime of the EUV pellicle on the basis of the estimated density.

2. The method of claim 1, wherein the wavelength band in the step a) comprises a wavelength band from 190 nm to 200 μm.

3. The method of claim 1, wherein the wavelength band in the step a) comprises a wavelength band from 190 nm to 1000 nm.

4. The method of claim 1, wherein the step a) comprises:
a-1) acquiring transmittance data in the wavelength band from 770 nm to 200 μm using an FT-IR type spectrometer; and
a-2) acquiring transmittance data in the wavelength band from 190 nm to 1000 nm using a UV-Vis type spectrophotometer.

5. The method of claim 1, wherein the step b) comprises:
b-1) attaching a pellicle membrane of the EUV pellicle to a substrate; and
b-2) acquiring complex refractive index data of the EUV pellicle using a spectroscopic ellipsometer.

6. The method of claim 1, wherein the step c) is a step that uses Intensity Transfer Matrix Method.

7. The method of claim 1, wherein the step d) comprises:
d-1) selecting at least one measurement beam;
d-2) measuring transmittance of the EUV pellicle for the selected measurement beam;
d-3) extracting an estimated density of the EUV pellicle on the basis of the transmittance measured in the step d-2) and information on the relationship between density and transmittance of the EUV pellicle acquired in the step c); and
d-4) predicting a remaining lifetime of the EUV pellicle on the basis of the estimated density extracted in the step d-3).

8. The method of claim 7, wherein the step d-1) comprises:
identifying an absorption mode that most significantly contributes to the amount of absorption of a pellicle membrane;
determining g a full width at half maximum (FWHM) of the absorption mode;
an FWHM outer wavelength range selection step of selecting a region outside the FWHM on the basis of the FWHM of the absorption mode; and
selecting a wavelength of the measurement beam in the selected wavelength range outside the FWHM.

9. The method of claim 8, wherein the selecting a wavelength of the measurement beam comprises:
a linear characteristic evaluation step of identifying a wavelength at which transmittance varies linearly with changes in density in the selected wavelength range outside the FWHM; and
a wavelength selection step of selecting a wavelength at which the linear relationship is most pronounced as the wavelength of the measurement beam.
